(19) United States
(12) Patent Application Publication
(10) Pub. No.: US 2026/0244400 A1
(43) Pub. Date: Aug. 20, 2026

(54) CIRCUIT OF ADDER TREE AND METHOD OF OPERATING THE SAME

(71) Applicants: TAIWAN SEMICONDUCTOR MANUFACTURING COMPANY, LTD., Hsinchu (TW); NATIONAL TSING HUA UNIVERSITY, Hsinchu City (TW)

(72) Inventors: Win-San KHWA, Taipei City (TW); Jun-Ming HSU, Hsinchu City (TW); Ping-Chun WU, Taichung City (TW); Meng-Fan CHANG, Taichung City (TW)

(73) Assignees: TAIWAN SEMICONDUCTOR MANUFACTURING COMPANY, LTD., Hsinchu (TW); NATIONAL TSING HUA UNIVERSITY, Hsinchu City (TW)

(21) Appl. No.: 19/054,098

(22) Filed: Feb. 14, 2025

(51) Int. Cl. G06F 7/501; H03K 19/08; H03K 19/21

(52) U.S. Cl. CPC G06F 7/501; H03K 19/08; H03K 19/21

(57) ABSTRACT

A circuit is provided. The circuit comprises first and second plurality of tree structures of adders. The first plurality of tree structures perform additions of bits lower than a place value of a plurality of numbers. The adders in the first plurality of tree structures generate full swing outputs. The second plurality of tree structures of adders are coupled to the first plurality of tree structures of adders. The second plurality of tree structures perform additions of bits equal to or higher than the place value of the plurality of numbers. The second plurality of tree structures include transistors fewer than transistors of the first plurality of tree structures. One of the adders in the second plurality of tree structures generates a non full swing output in response to bits inputted to the adder in the second plurality of tree structures matching a pattern.

### BACKGROUND

Artificial intelligence (AI) including machine learning (ML) is widely used in many cognitive tasks, such as image classification and speech recognition. For the efficient processing of workloads of such tasks, hardware has developed to have specific features for AI, e.g., specialized dataflow, compute-in-memory (CIM) architecture and near-memory computing (NMC) architecture. Such specifically designed hardware is referred to as an AI accelerator. With the increasing need of AI application, research on AI accelerators has gained more attention over the years.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram showing an AI accelerator, in accordance with various embodiments of the present disclosure.

FIG. 2 is a schematic diagram showing an example of the adder tree of the AI accelerator in FIG. 1, in accordance with various embodiments of the present disclosure.

FIG. 3 is a schematic diagram showing an example of the adder tree in FIGS. 1-2, in accordance with various embodiments of the present disclosure.

FIG. 4 is a schematic diagram showing an example of the adder tree in FIGS. 1-3, in accordance with various embodiments of the present disclosure.

FIG. 5 is a schematic diagram showing an example of a 28T adder of the adder in FIGS. 1-4, in accordance with various embodiments of the present disclosure.

FIG. 6 is a schematic diagram showing an example of a 14T adder of the adder in FIGS. 1-4, in accordance with various embodiments of the present disclosure.

FIG. 7 is a schematic diagram showing an example of the adder in FIGS. 1-4, in accordance with various embodiments of the present disclosure.

FIGS. 8A-8C are schematic diagrams showing XOR gates which are examples of the XOR gate in FIG. 7, in accordance with various embodiments of the present disclosure.

FIGS. 9A-9C are schematic diagrams showing XOR gate which are examples of the XOR gate in FIG. 7, in accordance with various embodiments of the present disclosure.

FIGS. 10A-10C are schematic diagrams showing MUXs which are example of the MUX in FIG. 7, in accordance with various embodiments of the present disclosure.

FIG. 11 is a schematic diagram showing an example of the adder in FIGS. 1-4 and 7, in accordance with various embodiments of the present disclosure.

FIG. 12 is a timing diagram showing an example of the voltages at the input terminals, the terminals and the output terminal of the adder in FIG. 11, in accordance with various embodiments of the present disclosure.

FIG. 13 is a schematic diagram showing an example of the adder in FIGS. 1-4, in accordance with various embodiments of the present disclosure.

FIGS. 14A-14C are schematic diagrams showing XNOR gates which are examples of the XNOR gate in FIG. 13, in accordance with various embodiments of the present disclosure.

FIGS. 15A-15C are schematic diagrams showing XNOR gates which are examples of the XNOR gate in FIG. 13, in accordance with various embodiments of the present disclosure.

FIGS. 16A-16C are schematic diagrams showing MUXs which are examples of the MUX in FIG. 13, in accordance with various embodiments of the present disclosure.

FIG. 17 is a schematic diagram showing an example of the adder in FIGS. 1-4 and 13, in accordance with various embodiments of the present disclosure.

FIG. 18 is a timing diagram showing an example of the voltages at the input terminals, the terminals and the output termina of the adder in FIG. 17, in accordance with various embodiments of the present disclosure.

FIGS. 19-20 are schematic diagrams showing examples of the adder tree in FIGS. 1-4, in accordance with various embodiments of the present disclosure.

FIG. 21 is a flowchart diagram of a method for operating the AI accelerator, the adder tree, and the adder as shown in FIGS. 1-7, 8A-8C, 9A-9C, 10A-10C, 11-13, 14A-14C, 15A-15C, 16A-16C, 17-20 in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

Edge artificial intelligence (AI) involves the deployment of AI algorithms and models directly on edge devices, which provides advantages including privacy, low latency, and more reliable and effective use of network bandwidth. However, for an edge device, energy and area are usually limited. Therefore, energy and area efficiency is important in designing AI accelerators within edge devices. In an AI accelerator, adders usually occupy a significant portion of area (e.g., 52%) and consume most power (e.g., 46%). The embodiments of the present disclosure provide adder architectures with improved energy and area efficiency, which help meet the energy and area constraints of AI accelerators.

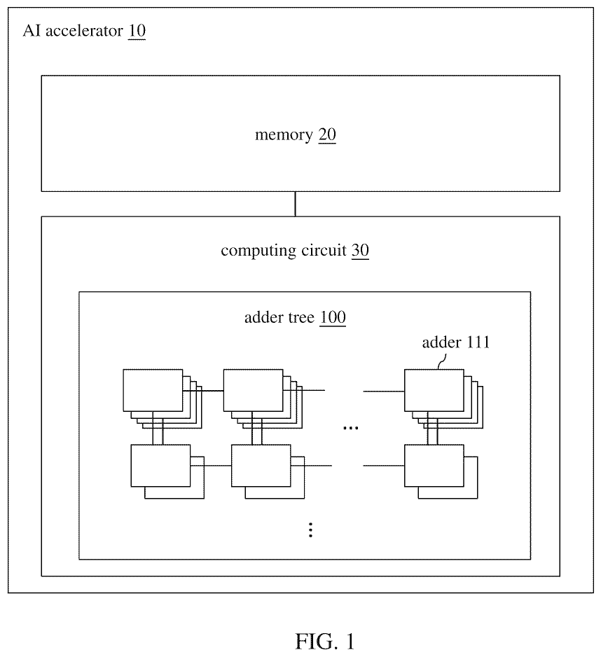

Reference is now made to FIG. 1. FIG. 1 is a schematic diagram showing an AI accelerator 10, in accordance with various embodiments of the present disclosure. For ease of understanding, throughout the various views and illustrative embodiments, like annotations and reference numbers are used to designate like elements. In some embodiments, the AI accelerator 10 is an electronic device including integrated circuits.

For practical applications, the AI accelerator 10 may be utilized in various AI application fields such as machine vision, image classification, or data classification. For example, the AI accelerator 10 may be used for classifying medical images. For example, the AI accelerator 10 can be used to classify X-ray images in normal conditions, with pneumonia, with bronchitis, or with heart disease. The AI accelerator 10 may also be used to classify ultrasound images with normal fetuses or abnormal fetal positions. On the other hand, the AI accelerator 10 can also be used to classify images collected in automatic driving, such as distinguishing normal roads, roads with obstacles, and road conditions images of other vehicles. Furthermore, the AI accelerator 10 can be utilized in other similar fields, such like music spectrum recognition, spectral recognition, big data analysis, data feature recognition and other related AI application fields.

As shown in FIG. 1, according to various embodiments, the AI accelerator 10 may include a memory 20 and a computing circuit 30 coupled to the memory 20. In some embodiments, the memory 20 is configured to store weights and/or inputs of an AI model corresponding to the AI application of the AI accelerator 10, e.g., weights of layers of a neural network. In some embodiments, the computing circuit 30 is configured to perform operations of the AI model, e.g., multiply-and-accumulate (MAC) operations between the weights and inputs of the AI model.

In some embodiments, the computing circuit 30 includes an adder tree 100 for performing additions in the AI operations. For example, the adder tree 100 performs the addition in the MAC operation of the computing circuit 30.

In some embodiments, the adder tree 100 includes multiple adders 111. The adders 111 are arranged into tree structures to generate a sum of multiple inputs to the adder tree 100. Further details will be described in the following paragraphs.

In some embodiments, the adder tree 100 may be utilized in application aside from an AI accelerator. The adder tree 100 may be utilized in any suitable circuit requiring operations of addition between multiple numbers.

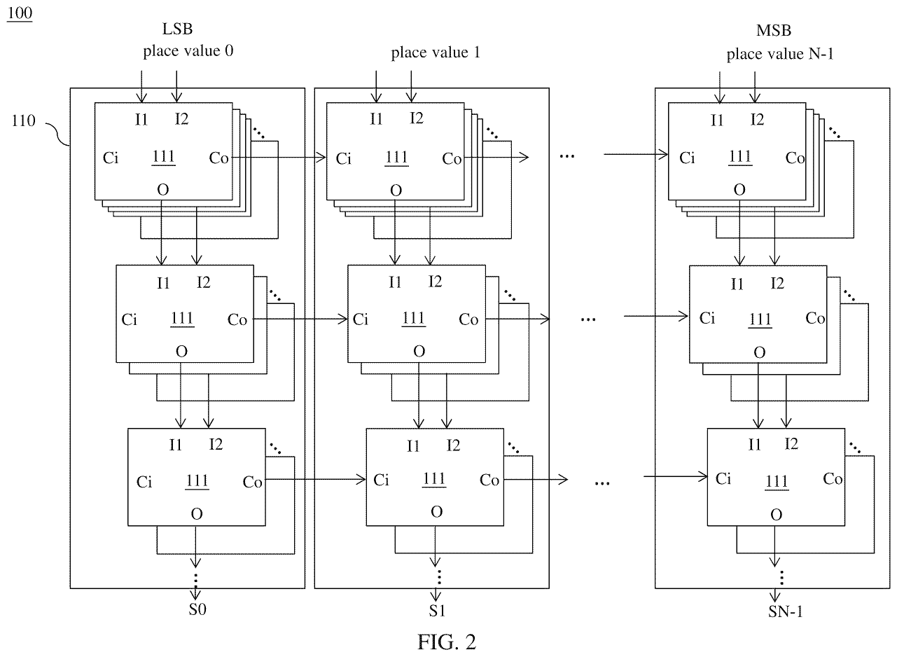

Reference is now made to FIG. 2. FIG. 2 is a schematic diagram showing an example of the adder tree 100 of the AI accelerator 10 in FIG. 1, in accordance with various embodiments of the present disclosure. The specific operations of similar elements, which are already discussed in detail previously, are omitted for the sake of brevity.

In some embodiments, the adder tree 100 is configured to perform additions between multiple N-bit numbers inputted to the adder tree 100 to generate a sum S of the N-bit numbers, in which N denotes an integer. For illustration, the adder tree 100 includes N structures 110. Each structure 110 is configured to perform additions of bits corresponding to a place value of the N-bit numbers. For example, the leftmost structure 110 in FIG. 2 performs additions between least significant bits (LSB), i.e., the bits of place value 0, of the N-bit numbers. The rightmost structure 110 in FIG. 2 performs additions between most significant bits (MSB), i.e., the bits of place value N−1, of the N-bit numbers.

As shown in FIG. 2, the N structures 110 perform the additions to generate bits S0 to SN−1 respectively. The bits S0 to SN−1 are bits corresponding to the place value 0 to the place value N−1 of the sum S of the N-bit numbers inputted to the adder trees.

For illustration, the structure 110 includes adders 111 arranged into a binary tree structure. Each adder 111 includes input terminals I1, I2 and an output terminal O. In some embodiments, the adder 111 performs binary addition between the bits received from the input terminals I1 and I2. Then, the adder 111 outputs the result of the binary addition through the output terminal O.

In some embodiments, each adder 111 in a first layer, i.e., the top layer shown in FIG. 2, of the structure 110 receives two bits corresponding to two of the inputted N-bit numbers separately to generate a sum. Each adder 111 in a second layer receives two sums generated by two of the adders 111 in the first layer to generate a sum. Then, the adders 111 in the subsequent layers operate in a similar manner to generate a final sum, e.g., the bit S0.

In some embodiments, the adder 111 is a full adder. Specifically, the adder 111 further includes a terminal Ci to receive an input carry and a terminal Co to generate an output carry. The adder 111 performs an addition of the bits received from the input terminals I1, I2 and the terminal Ci. Then, the adder 111 generates a sum of the addition at the output terminal O, and generates an output carry of the addition at the terminal Co.

As shown in FIG. 2, in order to perform the addition of the N-bit numbers with carry, the terminal Ci of each adder 111 in a structure 110 corresponding to a higher place value is coupled to the terminal Co of a corresponding adder 111 in a structure 110 corresponding to a lower place value. For example, the terminal Ci of each adder 111 in the structure 110 corresponding to the place value 1 is coupled to the terminal Co of a corresponding adder 111 in the structure 110 corresponding to the place value 0.

In some embodiments, the terminal Ci of each adder 111 in a structure 110 corresponding to the place value 0 is configured to receive a bit of zero when performing the addition of the N-bit numbers.

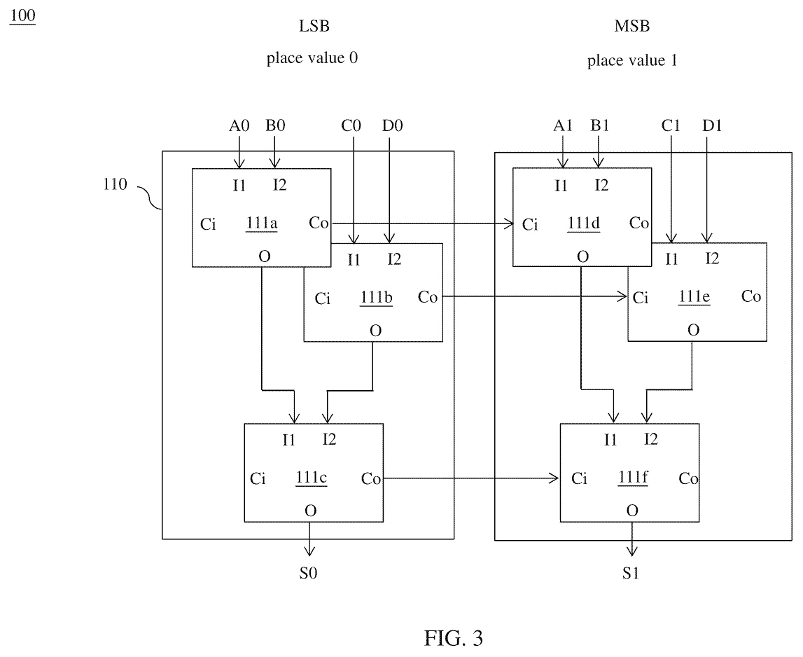

For ease of understanding, an example of the adder tree 100 with a minimized size is provided in FIG. 3 for explanation.

Reference is now made to FIG. 3. FIG. 3 is a schematic diagram showing an example of the adder tree 100 in FIGS. 1-2, in accordance with various embodiments of the present disclosure.

In the embodiment of FIG. 3, the adder tree 100 includes six adders 111 that are further annotated as adders 111a-111f separately. The adder tree 100 is configured to perform addition between 2-bit numbers inputted to the adder tree 100. For example, the adder tree 100 perform an addition between numbers A, B, C, and D to generate a sum S, in which numbers A, B, C, and D include bits A0-A1, bits B0-B1, bits C0-C1, and bits D0-D1 respectively.

In the structure 110 corresponding to the place value 0, the adders 111 in the first layer, i.e., the adders 111a and 111b, receive the bits of the place value 0 of the numbers A-D. Specifically, the adder 111a receives the bits A0 and B0, and the adder 111b receives the bits C0 and DO.

Then, the adder 111a generates the sum of the bits A0-B0, and the adder lib generates the sum of the bits C0-DO. The sums generated by the adders in the first layer are subsequently outputted to the adder 111 in a second layer of the structure 110 corresponding to the place value 0. For example, the sum of the bits A0-B0 and the sum of the bits C0-DO are outputted to the adder 111c. The adder 111c performs an addition and generate the bit S0 that is the bit, of the sum S, corresponding to the place value 0.

The adders 111d-111f in the structure 110 corresponding to the place value 1 operate in a manner similar to that of the adders 111a-111c to generate the bit Si that is the bit, of the sum S, corresponding to the place value 1. The difference between the adders 111d-111f and the adders 111a-111c is that the adders 111d-111f receive the output carries of the adders 111a-111c to perform the additions.

As shown in FIG. 3, the adder 111 performing addition to bits corresponding to a lower place value of two numbers generates the output carry to the adder 111 performing addition to bits corresponding to a higher place value of the two numbers. For example, the adder 111a performs the addition between the bits A0-B0 to generate an output carry to the adder 111d. Then, the adder 111d performs the addition between the bits A1-B1 and the output carry from the adder 111a.

Take the numbers A and B both being “01” for example. The adder 111a performs an addition between the first bit “1” of the number A and the first bit “1” of the number B to generate a sum of “0” and an output carry of “1”. The adder 111d performs an addition between the second bit “0” of the number A, the second bit “0” of the number B and the output carry of “1” to generate a sum of “1”.

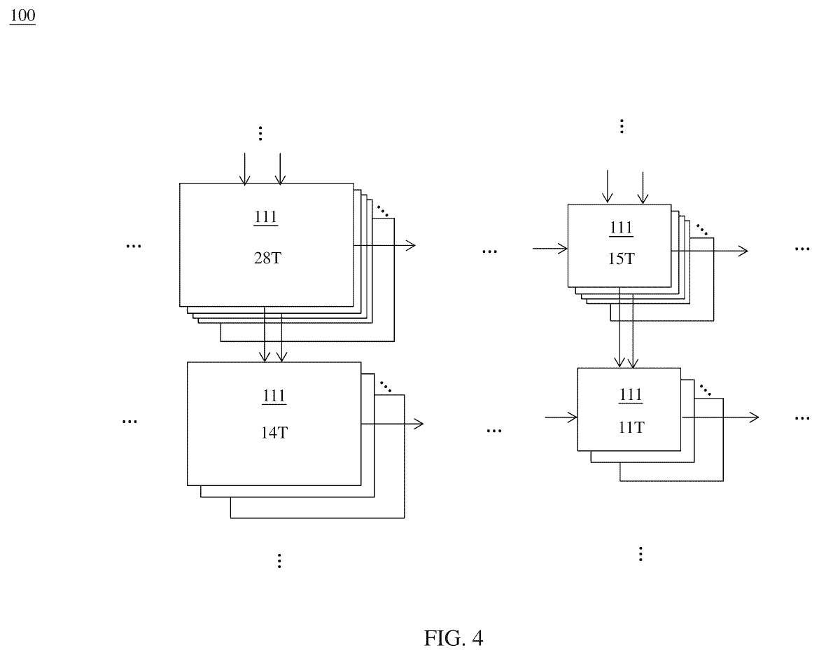

Reference is now made to FIG. 4. FIG. 4 is a schematic diagram showing an example of the adder tree 100 in FIGS. 1-3, in accordance with various embodiments of the present disclosure.

In some embodiments, the adder tree 100 includes different types of adder 111 which are composed of different amounts of transistors. For example, the adder 111 may be a 28T adder, i.e., an adder composed of 28 transistors. According to various embodiments, the adder 111 may also be one of a 15T adder, a 14T adder, a 11T adder, etc.

According to various embodiments, adder 111 with fewer transistors consumes lower power and smaller area. However, adder 111 with more transistors may have some advantages, e.g., better driving force.

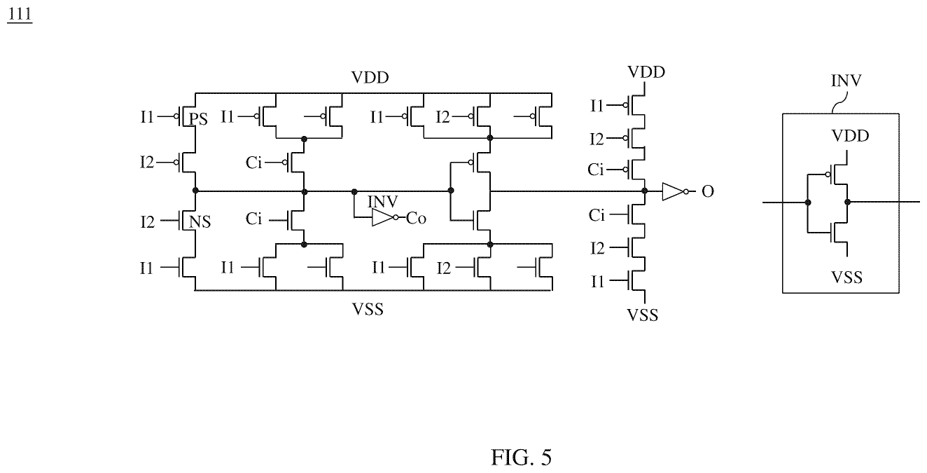

Reference is now made to FIG. 5. FIG. 5 is a schematic diagram showing an example of a 28T adder of the adder 111 in FIGS. 1-4, in accordance with various embodiments of the present disclosure.

As shown in FIG. 5, the adder 111 that is a 28T adder includes transistors coupled between a supply voltage VDD and a supply voltage VSS. In some embodiments, the supply voltage VDD is higher than the supply voltage VSS. In some embodiments, the supply voltage VSS is a ground voltage.

As shown in FIG. 5, the adder 111 includes transistors PS which are P type metal-oxide-semiconductor field-effect transistors (PMOS) and transistors NS which are N type metal-oxide-semiconductor field-effect transistors (NMOS). The adder 111 further includes inverters INV. In some embodiments, each of the inverters INV is composed of a PMOS and an NMOS coupled in series between the supply voltage VDD and the supply voltage VSS. The 28T adder 111 provides a full swing output, i.e., the voltage levels at the output terminal O and the terminal Co range from the level of the supply voltage VDD to the level of the supply voltage VSS. In addition, the voltages at the output terminal O and the terminal Co are directly driven by the supply voltages VDD and VSS. For example, either the transistor PS in the inverter INV transmits the supply voltage VDD to the output terminal O or the transistor NS in the inverter INV transmits the supply voltage VSS to the output terminal O.

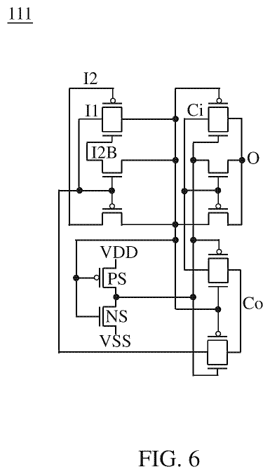

Reference is now made to FIG. 6. FIG. 6 is a schematic diagram showing an example of a 14T adder of the adder 111 in FIGS. 1-4, in accordance with various embodiments of the present disclosure.

As shown in FIG. 6, the adder 111 includes 7 transistors PS and 7 transistors NS. The adder 111 further includes a terminal I2B which is configured to receive a voltage inverted to the voltage at the input terminal I2. For example, when the voltage at the input terminal I2 is the supply voltage VDD, the voltage at the input terminal I2B is the supply voltage VSS, and vice versa. The 14T adder 111 provides a full swing output. The voltages at the output terminal O and the terminal Co are driven by the voltages from input terminals I1, I2 and the terminal I2B.

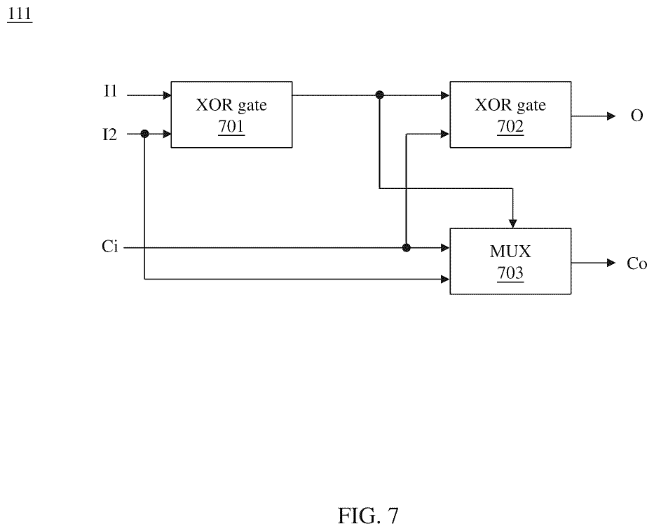

Reference is now made to FIG. 7. FIG. 7 is a schematic diagram showing an example of the adder 111 in FIGS. 1-4, in accordance with various embodiments of the present disclosure.

As shown in FIG. 7, the adder 111 includes an exclusive OR (XOR) gate 701, an XOR gate 702 and a multiplexer (MUX) 703. The input terminals of the XOR gate 701 are coupled to the input terminals I1 and I2. The input terminals of the XOR gate 702 are coupled to an output terminal of the XOR gate 701 and the terminal Ci. The input terminals of the MUX 703 are coupled to the input terminal I2 and the terminal Ci. The output terminal of the MUX 703 is coupled to the terminal Co. The MUX 703 selects signals from the input terminal I2 or the terminal Ci to transmit to the terminal Co according to the output signal of the XOR gate 701.

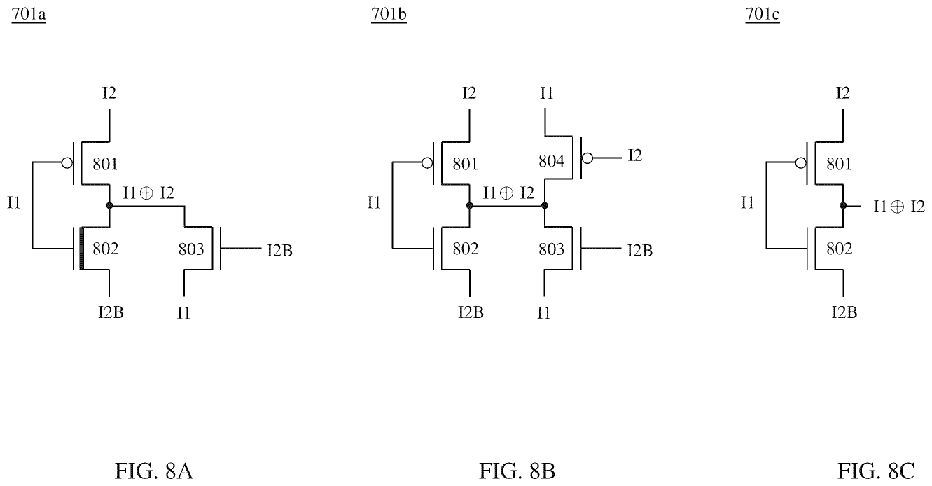

Reference is now made to FIG. 8A. FIG. 8A is a schematic diagram showing an XOR gate 701a which is an example of the XOR gate 701 in FIG. 7, in accordance with various embodiments of the present disclosure.

In some embodiments, the XOR gate 701a is a pattern-dependent full swing XOR gate. Specifically, the output of the XOR gate 701a is full swing when the inputs to the input terminals I1 and I2 match critical pattern and the output of the XOR gate 701a is non full swing when the inputs to the input terminals I1 and I2 don't match the critical pattern. According to some embodiments, being “non full swing” refers to (1) transferring the supply voltage VDD through NMOS to generate the output or (2) transferring the supply voltage VSS through PMOS to generate the output.

Specifically, a threshold drop issue will occur when an NMOS transferring the supply voltage VDD or the PMOS transferring the supply voltage VSS. For example, the output generated by an NMOS transferring the supply voltage VDD may be the supply voltage VDD minus the threshold voltage Vth of the NMOS. Similarly, the output generated by a PMOS transferring the supply voltage VSS may be the supply voltage VSS plus the threshold voltage Vth of the PMOS.

Compared with a full swing XOR gate in some approaches, the pattern-dependent full swing XOR gate uses fewer transistors and consumes less area and energy.

For example, in some embodiments, the inputs to the input terminals I1 and I2 match critical pattern for the XOR gate 701a to be full swing when the bits to the input terminals I1 and I2 are bits “01”, in which transmitting bits “01” to the input terminals I1 and I2 refers to transmitting “0” and “1” to the input terminals I1 and I2 respectively. According to some embodiments, transmitting a bit “0” refers to transmitting the supply voltage VSS and transmitting a bit “1” refers to transmitting the supply voltage VDD.

In some embodiments, the XOR gate 701a includes three transistors. In some embodiments, one of the three transistors has a threshold voltage lower than that of the other two transistors. In some embodiments, one of the transistors is an ultra-low voltage threshold (ULVT) MOS while the other two transistors are standard voltage threshold (SVT) MOSs. The transistor having the lower threshold voltage is the NMOS to transfer the supply voltage VDD or the PMOS to transfer the supply voltage VSS for generating the non full swing output. According to some embodiments, the transistor is configured to have the lower threshold voltage (e.g., ULVT) to mitigate the impact by the threshold drop.

For example, as shown in FIG. 8A, in some embodiments, the XOR gate 701a includes transistors 801-803. In some embodiments, the transistor 801 is a PMOS and the transistors 802 and 803 are NMOSs. In some embodiments, the transistor 802 has a threshold voltage lower than the threshold voltage of the transistors 801 and 803. In some embodiments, the transistor 802 is an ULVT MOS and the transistors 801 and 803 are SVT MOSs.

For illustration, the transistor 801 is coupled between the input terminal I2 and a terminal I1⊕I2. The terminal I1⊕I2 is an output terminal of the XOR gate 701a to output the result of exclusive OR operation between the inputs from the input terminals I1 and I2.

The transistor 802 is coupled between the terminal I1⊕I2 and the terminal I2B, in which the terminal I2B is configured to receive a voltage inverted to the voltage at the input terminal I2.

A gate of the transistor 801 and a gate of the transistor 802 are coupled together to the input terminal I1.

The transistor 803 is coupled between the terminal I1⊕I2 and the input terminal I1. A gate of the transistor 803 is coupled to the terminal I2B.

For the XOR gate 701a shown in FIG. 8A, the critical patterns to the input terminals I2 and 12 are bits “00”, “01” and “11”. As described above, when the bits to the input terminals I1 and I2 match the critical patterns, e.g., the bits being “01”, the XOR gate 701a generates full swing output of the exclusive OR operation between the bits.

Reference is now made to FIG. 8B. FIG. 8B is a schematic diagram showing an XOR gate 701b which is an example of the XOR gate 701 in FIG. 7, in accordance with various embodiments of the present disclosure.

The XOR gate 701b is configured with respect to the XOR gate 701a. Compared to the XOR gate 701a, the XOR gate 701b further includes a transistor 804. In some embodiments, the transistor 804 is a PMOS. In some embodiments, the transistor 804 is coupled between the input terminal I1 and the terminal I1⊕I2. A gate of the transistor 804 is coupled to the input terminal I2.

In some embodiments, the transistors 801-804 have a same threshold voltage. In some embodiments, the transistors 801-804 are SVT MOS.

The XOR gate 701b is a full swing XOR gate which generates full swing output for all patterns of input, i.e., bits “00”, “01”, ‘10’ and “11” to the input terminals I1 and I2.

Reference is now made to FIG. 8C. FIG. 8C is a schematic diagram showing an XOR gate 701c which is an example of the XOR gate 701 in FIG. 7, in accordance with various embodiments of the present disclosure.

The XOR gate 701c is configured with respect to the XOR gate 701a. Compared to the XOR gate 701a, the XOR gate 701c is a simple XOR gate that does not include the transistor 803. In some embodiments, the transistors 801-802 have a same threshold voltage. In some embodiments, the transistors 801-802 are SVT MOS.

In some embodiments, the transistor 801 is a PMOS and the transistor 802 is an NMOS. The critical patterns to the input terminals I1 and I2 to generate full swing outputs are bits “01” and “11”.

The configurations of FIGS. 8A-8C are given for illustrative purposes. Various implements are within the contemplated scope of the present disclosure. The XOR gates 701, 701a-701c may have different configurations to have different critical patterns. For example, in some embodiments, for the XOR gate 701a shown in FIG. 8A, the positions of input terminals I1 and I2 can be swapped, for example, the gates of the transistors 801-802 are coupled to the input terminal I2, and the terminal I2B is replaced by a terminal I1B which receives a voltage inverted to the voltage at the input terminal I1. In such case, the critical patterns are bits “00”, “10” and “11”.

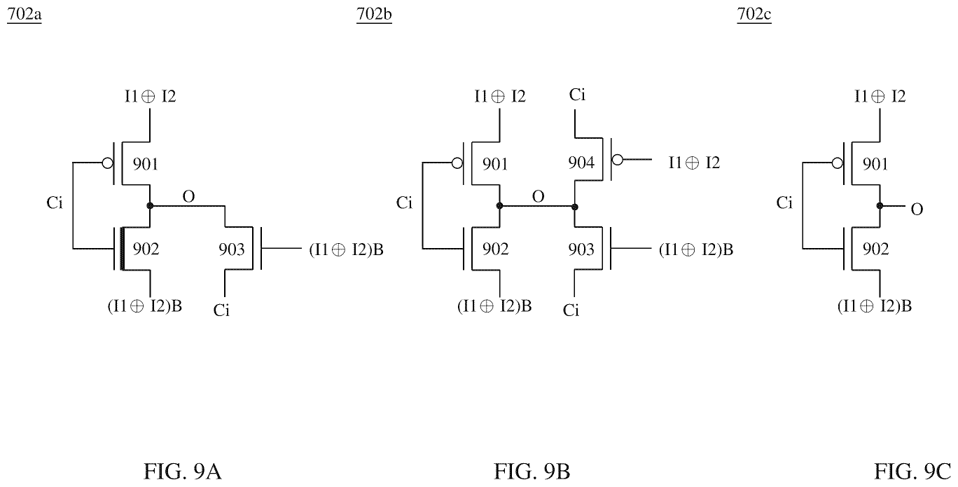

Reference is now made to FIG. 9A. FIG. 9A is a schematic diagram showing an XOR gate 702a which is an example of the XOR gate 702 in FIG. 7, in accordance with various embodiments of the present disclosure.

In some embodiments, the XOR gate 702a has configurations similar to that of the XOR gate 701a. For example, the XOR gate 702a is a pattern-dependent full swing XOR gate as described above.

As shown in FIG. 9A, in some embodiments, the XOR gate 702a includes transistors 901-903. In some embodiments, the transistor 901 is a PMOS and the transistors 902 and 903 are NMOSs. In some embodiments, the transistor 902 has a threshold voltage lower than the threshold voltage of the transistors 901 and 903. In some embodiments, the transistor 902 is an ULVT MOS and the transistors 901 and 903 are SVT MOSs.

For illustration, the transistor 901 is coupled between the terminal I1⊕I2 and the output terminal O. The output terminal O output the result of exclusive OR operation between the inputs from the terminal I1⊕I2 and the terminal Ci.

The transistor 902 is coupled between the output terminal O and a terminal (I1⊕I2)B, in which the terminal (I1⊕I2)B is configured to receive a voltage inverted to the voltage at the terminal I1⊕I2. Gates of the transistors 901-902 are coupled together to the terminal Ci.

The transistor 903 is coupled between the output terminal O and the terminal Ci. A gate of the transistor 803 is coupled to the terminal (I1⊕I2)B.

For the XOR gate 702a shown in FIG. 9A, the critical patterns to the terminals I1⊕I2 and Ci are bits “00”, “01” and “11”.

Reference is now made to FIGS. 9B-9C. FIGS. 9B-9C are schematic diagrams showing XOR gates 702b and 702c which are examples of the XOR gate 702 in FIG. 7, in accordance with various embodiments of the present disclosure.

The XOR gates 702b and 702c are configured with respect to the XOR gate 702a in a manner similar to that of the XOR gates 701b and 701c configured with respect to the XOR gate 701a. For example, the XOR gate 702b is a full swing XOR gate similar to the XOR gate 701b, and the XOR gate 702c is a simple XOR gate similar to the XOR gate 701c.

The configurations of FIGS. 9A-9C are given for illustrative purposes. Various implements are within the contemplated scope of the present disclosure. The XOR gates 702, 702a-702c may have different configurations to have different critical patterns. For example, in some embodiments, the XOR gate 702a shown in FIG. 9A, the positions of terminals I1⊕I2 and Ci may be swapped and the terminal (I1⊕I2)B is replaced by a terminal CiB which receives a voltage inverted to the voltage at the input terminal Ci. In such case, the critical patterns are bits “00”, “10” and “11”.

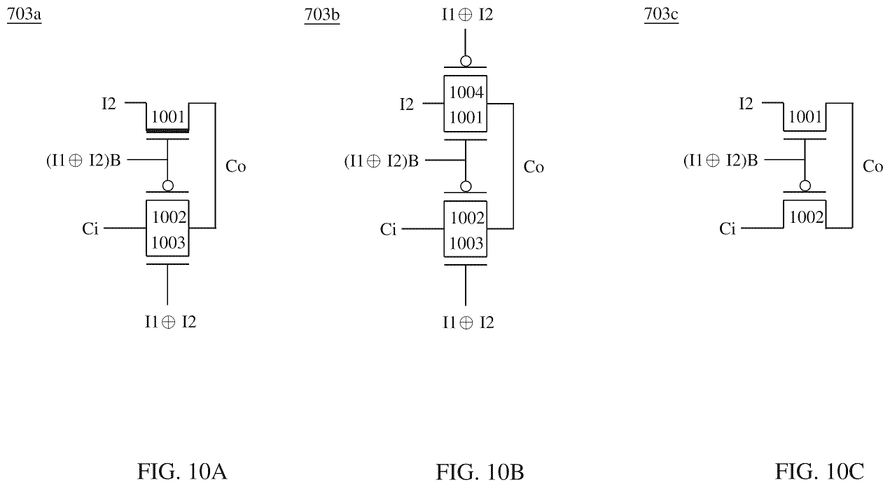

Reference is now made to FIG. 10A. FIG. 10A is a schematic diagram showing a MUX 703a which is an example of the MUX 703 in FIG. 7, in accordance with various embodiments of the present disclosure.

In some embodiments, the MUX 703a is a pattern-dependent full swing MUX. Specifically, the output of the MUX 703a is full swing when the inputs to the input terminals I2, terminals Ci and I1⊕I2 match critical pattern and the output of the XOR gate 701a is non full swing when the inputs to the input terminals I2, terminals Ci and I1⊕I2 don't match the critical pattern.

In some embodiments, the MUX 703a includes three transistors. In some embodiments, one of the three transistors has a threshold voltage lower than that of the other two transistors. In some embodiments, one of the transistors is an ultra-low voltage threshold (ULVT) MOS while the other two transistors are standard voltage threshold (SVT) MOSs. The transistor having the lower threshold voltage is the NMOS to transfer the supply voltage VDD or the PMOS to transfer the supply voltage VSS for generating the non full swing output.

For example, as shown in FIG. 10A, in some embodiments, the MUX 703a includes transistors 1001-1003. In some embodiments, the transistor 1002 is a PMOS and the transistors 1001 and 1003 are NMOSs. In some embodiments, the transistor 1001 has a threshold voltage lower than the threshold voltage of the transistors 1002 and 1003. In some embodiments, the transistor 1001 is an ULVT MOS and the transistors 1002 and 1003 are SVT MOSs.

For illustration, the transistor 1001 is coupled between the input terminal I2 and the terminal Co. The gate of the transistor 1001 is coupled to the terminal (I1⊕I2)B.

The transistor 1002 is coupled between the terminal Ci and the terminal Co. A gate of the transistor 1002 is coupled to the terminal (I1⊕I2)B.

The transistor 1003 is coupled between the terminal Ci and the terminal Co. A gate of the transistor 1003 is coupled to the terminal I1⊕I2.

For the MUX 703a shown in FIG. 10A, the critical patterns to the input terminal I2, the terminals Ci and (I1⊕I2)B are bits “0x1” and “xx0”, in which “x” denotes that the bit can be “0” or “1”. As described above, when the bits to the input terminal I2, the terminals Ci and (I1⊕I2)B match the critical patterns, e.g., the bits being “001”, the MUX 703a generates full swing output.

Reference is now made to FIG. 10B. FIG. 10B is a schematic diagram showing a MUX 703b which is an example of the MUX 703 in FIG. 7, in accordance with various embodiments of the present disclosure.

The MUX 703b is configured with respect to the MUX 703a. Compared to the MUX 703a, the MUX 703b further includes a transistor 1004. In some embodiments, the transistor 1004 is a PMOS. In some embodiments, the transistor 1004 is coupled between the input terminal I2 and the terminal Co. A gate of the transistor 1004 is coupled to the terminal I1⊕I2.

In some embodiments, the transistors 1001-1004 have a same threshold voltage. In some embodiments, the transistors 1001-1004 are SVT MOS.

The MUX 703b is a full swing MUX which generates full swing output for all patterns of input to the input terminal I2, the terminals Ci and (I1⊕I2)B.

Reference is now made to FIG. 10C. FIG. 10C is a schematic diagram showing an MUX 703c which is an example of the MUX 703 in FIG. 7, in accordance with various embodiments of the present disclosure.

The MUX 703c is configured with respect to the MUX 703a. Compared to the MUX 703a, the MUX 703c is a simple MUX that does not include the transistor 1003. In some embodiments, the transistors 1001-1002 have a same threshold voltage. In some embodiments, the transistors 1001-1002 are SVT MOS.

In some embodiments, the transistor 1001 is a NMOS and the transistor 1002 is an PMOS. The critical patterns to the input terminal I2, the terminals Ci and (I1⊕I2)B to generate full swing outputs are bits “0x1” and “x10”.

The configurations of FIGS. 10A-10C are given for illustrative purposes.

Various implements are within the contemplated scope of the present disclosure. The MUXs 703, 703a-703c may have different configurations to have different critical patterns. For example, in some embodiments, the MUX 703a shown in FIG. 10A further includes the transistor 1004 and does not include the transistor 1003. In such case, the critical patterns are bits “x10” and “xx1”.

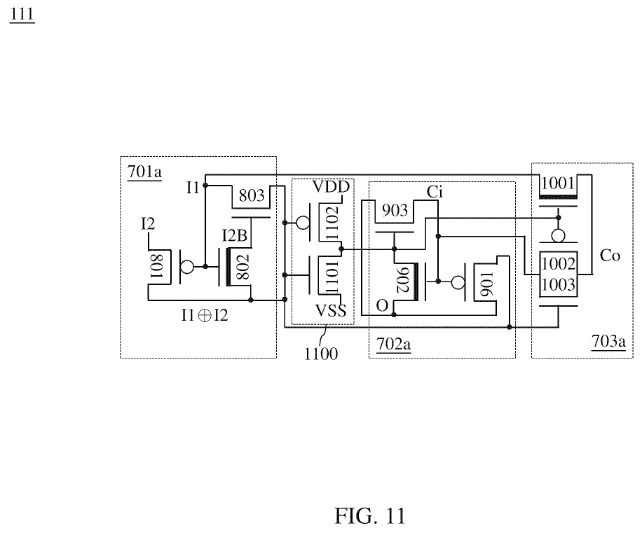

Reference is now made to FIG. 11. FIG. 11 is a schematic diagram showing an example of the adder 111 in FIGS. 1-4 and 7, in accordance with various embodiments of the present disclosure.

As shown in FIG. 11, in some embodiments, the adder 111 is an 11T adder including the XOR gates 701, 702, the MUX 703 and an inverter 1100. In some embodiments, the XOR gates 701, 702, the MUX 703 are the XOR gates 701a, 702a, the MUX 703a respectively. In some embodiments, the inverter 1100 is coupled between the terminal I1⊕I2 and the terminal (I1⊕I2)B to generate the inverted voltage at the terminal (I1⊕I2)B according to the voltage at the terminal I1⊕I2.

In some embodiments, the inverter 1100 includes a transistor 1101 and a transistor 1102. In some embodiments, the transistor 1101 is an NMOS and the transistor 1102 is a PMOS.

The following Table 1 shows the results of the bits generated by the 11T adder 111 at the terminals I1⊕I2, Co and the output terminal O in response to the bits inputted to the input terminals I1, I2, the terminal Ci.

TABLE 1

| I1 | I2 | Ci | I1⊕I2 | Co | O |
|---|---|---|---|---|---|
| 0 | 0 | 0 | 0 | 0 | 0 |
| 0 | 0 | 1 | 0 | 0 | 1* |
| 0 | 1 | 0 | 1 | 0 | 1 |
| 0 | 1 | 1 | 1 | 1 | 0 |
| 1 | 0 | 0 | 1* | 0 | 1 |
| 1 | 0 | 1 | 1* | 1 | 0 |
| 1 | 1 | 0 | 0 | 1* | 0 |
| 1 | 1 | 1 | 0 | 1* | 1* |

In Table 1, “1*” denotes a bit “1” which is non full swing. Specifically, in some embodiment, the voltage of the bit “1” is the supply voltage VDD, the voltage of the bit “1*” is the supply voltage VDD minus the threshold voltage Vth of the ULVT MOS, and the voltage of the bit “0” is the supply voltage VSS.

As shown in Table 1, the critical pattern of the adder 111 to generate full swing outputs in this case are bits “000”, “010” and “011” to the input terminals I1, I2 and the terminal Ci.

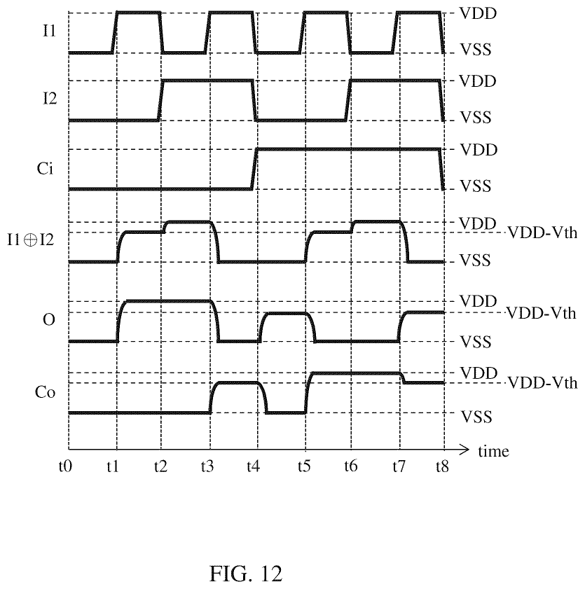

Reference is now made to FIG. 12. FIG. 12 is a timing diagram showing an example of the voltages at the input terminals I1-I2, the terminals Ci, I1⊕I2, Co and the output terminal O of the adder 111 in FIG. 11, in accordance with various embodiments of the present disclosure.

FIG. 12 shows voltages at different terminals of the adder 111 in FIG. 11 corresponding to different inputted bits from a time t0 to a time t8. For example, at the period between the time t1 and the time t2, the bits to the input terminals I1, I2 and the terminal Ci are “100”, i.e., the voltages to the input terminals I1, I2 and the terminal Ci are the supply voltage VDD, the supply voltage VSS and the supply voltage VSS respectively.

As shown in FIG. 12, in response to the voltages to the input terminals I1, I2 and the terminal Ci the time t1 and the time t2, the voltages at the terminal I1⊕I2, the output terminal O and the terminal Co are the supply voltage VDD minus the threshold voltage Vth (VDD-Vth), the supply voltage VDD and the supply voltage VSS respectively.

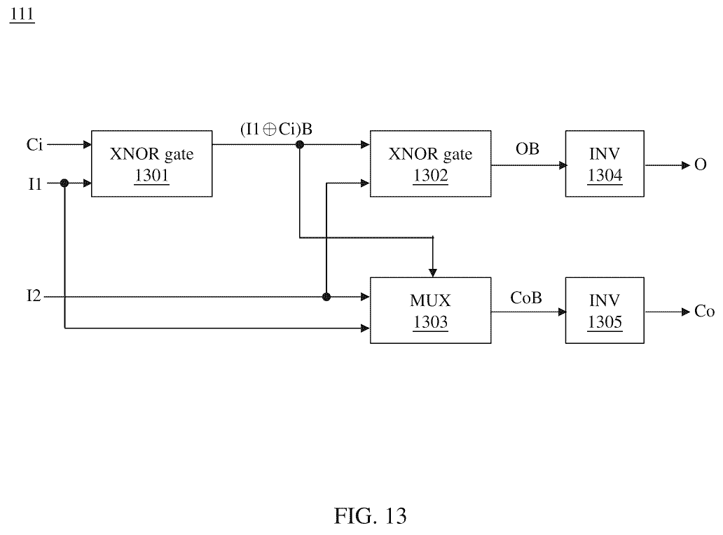

Reference is now made to FIG. 13. FIG. 13 is a schematic diagram showing an example of the adder 111 in FIGS. 1-4, in accordance with various embodiments of the present disclosure.

As shown in FIG. 13, the adder 111 includes an exclusive NOR (XNOR) gate 1301, an XNOR gate 1302 and a multiplexer (MUX) 1303, an inverter (INV) 1304 and an inverter 1305.

The input terminals of the XNOR gate 1301 are coupled to the input terminal I1 and the terminal Ci. The XNOR gate 1301 generates a voltage inverted to the exclusive OR of the voltages of the input terminal I1 and the terminal Ci at a terminal (I1⊕I2)B.

The input terminals of the XNOR gate 1302 are coupled to the terminal (I1⊕I2)B and the input terminal I2. The XNOR gate 1302 generates a voltage inverted to the exclusive OR of the voltages of the terminal (I1⊕I2)B and the input terminal I2 at a terminal OB. The inverter 1304 generates a voltage at the output terminal O inverted to the voltage at the terminal OB.

The input terminals of the MUX 1303 are coupled to the input terminals I1 and I2. The output terminal of the MUX 1303 is coupled to a terminal CoB. The MUX 1303 selects signals from the input terminals I1 or I2 to transmit to the terminal CoB according to the output signal of the XNOR gate 1301. The inverter 1305 generates a voltage at the terminal Co inverted to the voltage at the terminal CoB.

In some embodiments, similar to the adder 111 in FIG. 5, the adder 111 in FIG. 13 provides driving force to the output terminal O and the terminal Co from the supply voltages VDD and VSS through the inverters 1304 and 1305.

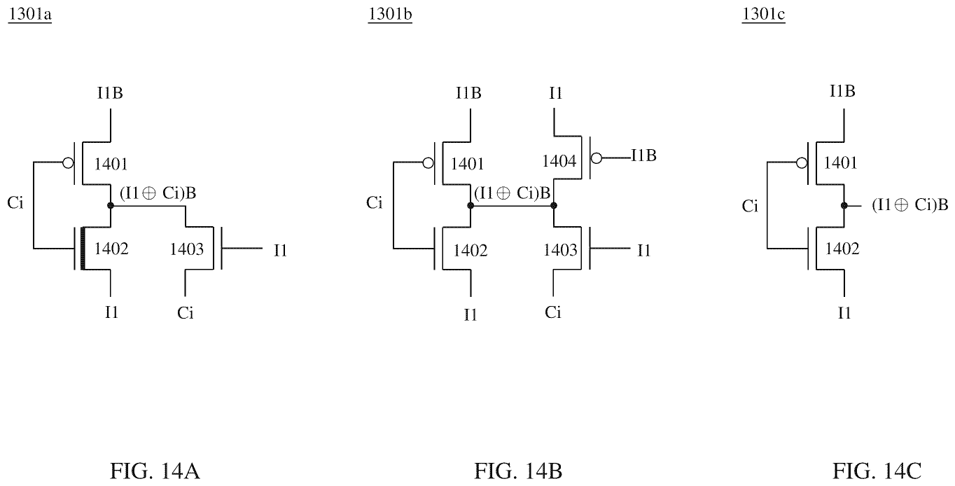

Reference is now made to FIGS. 14A-14C. FIGS. 14A-14C are schematic diagrams showing XNOR gates 1301a, 1301b, 1301c which are examples of the XNOR gate 1301 in FIG. 13, in accordance with various embodiments of the present disclosure.

As shown in FIG. 14A, the XNOR gate 1301a is a pattern-dependent full swing XNOR gate. The XNOR gate 1301a has configurations similar to those of the XOR gate 701a. For example, the XNOR gate 1301a includes three transistors 1401-1403. In some embodiments, the transistor 1401 is a PMOS and the transistors 1402 and 1403 are NMOSs. In some embodiments, the transistor 1402 has a threshold voltage lower than the threshold voltage of the transistors 1401 and 1403. In some embodiments, the transistor 1402 is an ULVT MOS and the transistors 1401 and 1403 are SVT MOSs.

As shown in FIGS. 14B-14C, the XNOR gate 1301b is a full swing XNOR gate having configurations similar to those of the XOR gate 701b. The XNOR gate 1301c is a simple XNOR gate having configurations similar to those of the XOR gate 701c.

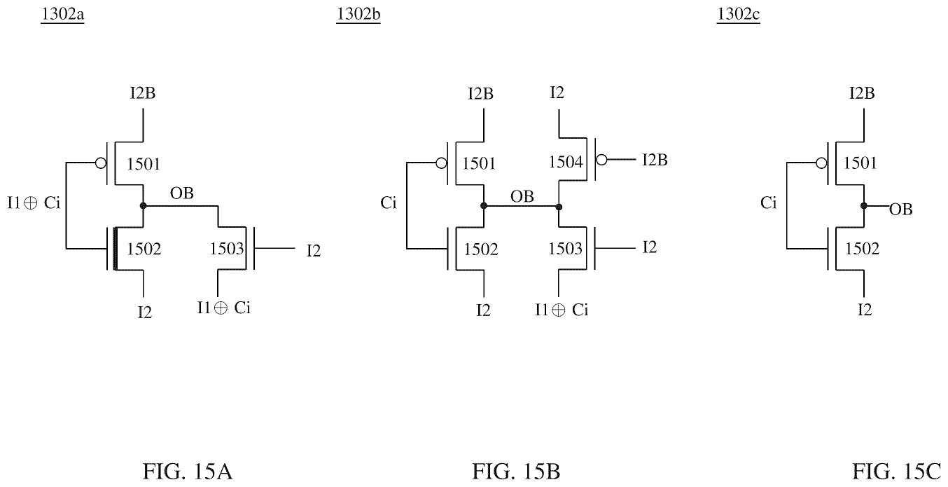

Reference is now made to FIGS. 15A-15C. FIGS. 15A-15C are schematic diagrams showing XNOR gates 1302a, 1302b, 1302c which are examples of the XNOR gate 1302 in FIG. 13, in accordance with various embodiments of the present disclosure.

The XNOR gates 1302a, 1302b, 1302c are a pattern-dependent full swing XNOR gate, a full swing XNOR gate and a simple XNOR. The XNOR gates 1302a, 1302b, 1302c have configurations similar to those of the XNOR gates 1301a, 1301b, 1301c. For example, the XNOR gate 1302a includes three transistors 1501-1503. In some embodiments, the transistor 1501 is a PMOS and the transistors 1502 and 1503 are NMOSs. In some embodiments, the transistor 1502 has a threshold voltage lower than the threshold voltage of the transistors 1501 and 1503. In some embodiments, the transistor 1502 is an ULVT MOS and the transistors 1501 and 1503 are SVT MOSs.

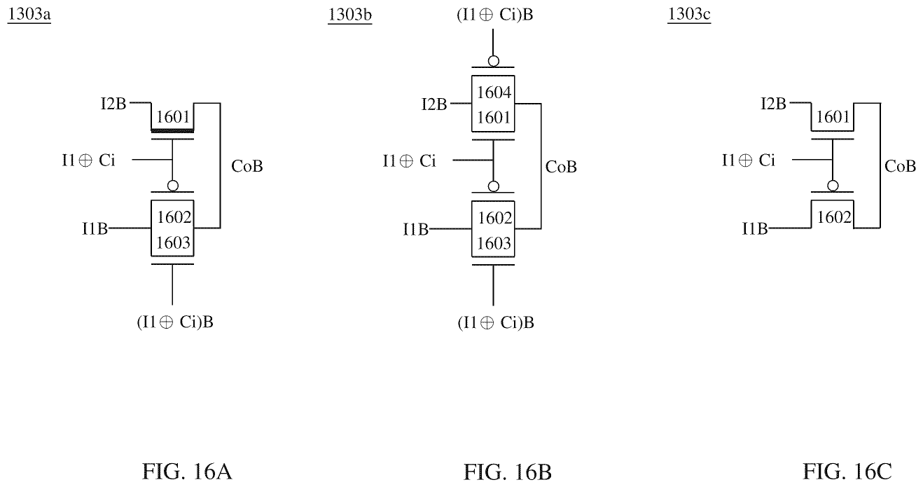

Reference is now made to FIGS. 16A-16C. FIGS. 16A-16C are schematic diagrams showing MUXs 1303a, 1303b, 1303c which are examples of the MUX 1303 in FIG. 13, in accordance with various embodiments of the present disclosure.

The MUX 1303a, 1303b, 1303c are a pattern-dependent full swing MUX, a full swing MUX and a simple MUX. The MUXs 1303a, 1303b, 1303c have configurations similar to those of the MUXs 703a, 703b, 703c. For example, the MUX 1303a includes transistors 1601-1603. In some embodiments, the transistor 1602 is a PMOS and the transistors 1601 and 1603 are NMOSs. In some embodiments, the transistor 1601 has a threshold voltage lower than the threshold voltage of the transistors 1602 and 1603. In some embodiments, the transistor 1601 is an ULVT MOS and the transistors 1602 and 1603 are SVT MOSs.

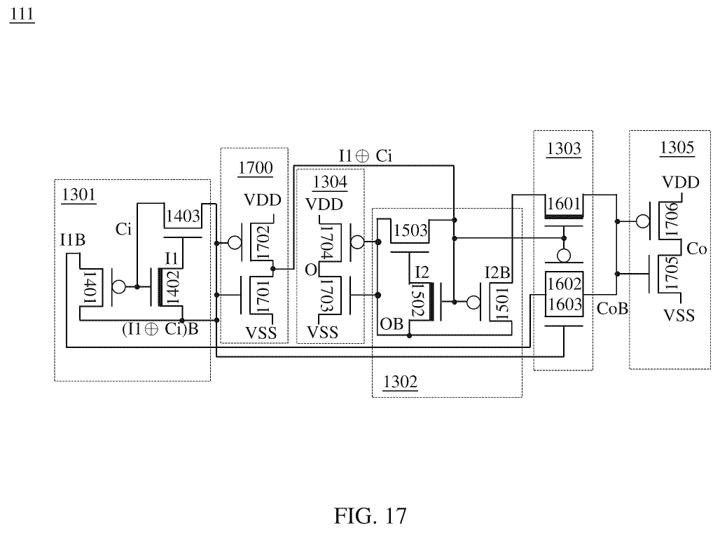

Reference is now made to FIG. 17. FIG. 17 is a schematic diagram showing an example of the adder 111 in FIGS. 1-4 and 13, in accordance with various embodiments of the present disclosure.

As shown in FIG. 17, in some embodiments, the adder 111 is an 15T adder including the XNOR gates 1301, 1302, the MUX 1303 and an inverters 1304, 1305, 1700. In some embodiments, the XOR gates 1301, 1302, the MUX 1303 are the XOR gates 1301a, 1302a, the MUX 1303a respectively. In some embodiments, the inverter 1700 is coupled between the terminal (I1⊕I2)B and the terminal I1⊕I2 to generate the inverted voltage at the terminal I1⊕I2 according to the voltage at the terminal (I1⊕I2)B.

In some embodiments, the inverter 1100 includes a transistor 1701 and a transistor 1702. The inverter 1304 includes a transistor 1703 and a transistor 1704. The inverter 1305 includes a transistor 1705 and a transistor 1706. In some embodiments, the transistor 1701, 1703, 1705 are NMOSs and the transistor 1702, 1704, 1706 are PMOSs.

The following Table 2 shows the results of the bits generated by the 15T adder 111 at the terminals (I1⊕I2)B, CoB and the output terminal OB in response to the bits inputted to the input terminals I1, I2, the terminal Ci.

TABLE 2

| I1 | I2 | Ci | (I1⊕I2)B | CoB | OB |
|---|---|---|---|---|---|
| 0 | 0 | 0 | 1 | 1 | 1 |
| 0 | 0 | 1 | 0 | 1* | 0 |
| 0 | 1 | 0 | 1 | 1 | 0 |
| 0 | 1 | 1 | 0 | 0 | 1* |
| 1 | 0 | 0 | 0 | 1* | 0 |
| 1 | 0 | 1 | 1* | 0 | 1 |
| 1 | 1 | 0 | 0 | 0 | 1* |
| 1 | 1 | 1 | 1* | 0 | 0 |

As shown in Table 2, the critical pattern of the adder 111 to generate full swing outputs at the terminal (I1⊕I2)B, OB and CoB in this case are bits “000” and “010” to the input terminals I1, I2 and the terminal Ci.

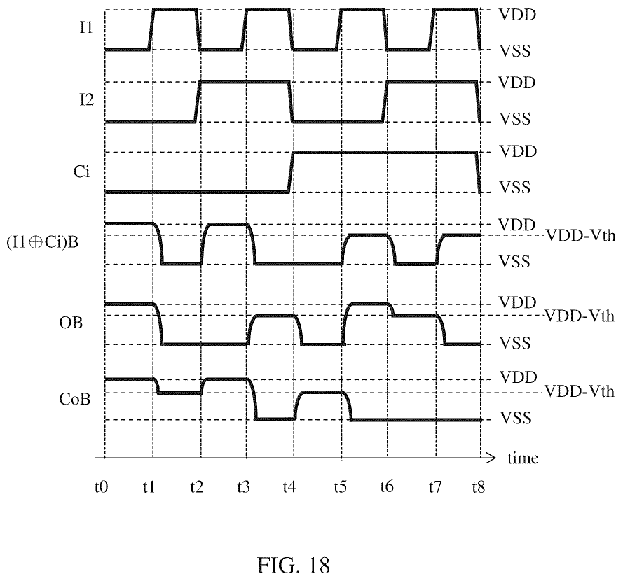

Reference is now made to FIG. 18. FIG. 18 is a timing diagram showing an example of the voltages at the input terminals I1-I2, the terminals Ci, (I1⊕I2)B, CoB and the output terminal OB of the adder 111 in FIG. 17, in accordance with various embodiments of the present disclosure.

FIG. 18 shows voltages at different terminals of the adder 111 in FIG. 17 corresponding to different inputted bits from a time t0 to a time t8. For example, at the period between the time t1 and the time t2, the bits to the input terminals I1, I2 and the terminal Ci are “100”, i.e., the voltages to the input terminals I1, I2 and the terminal Ci are the supply voltage VDD, the supply voltage VSS and the supply voltage VSS respectively.

As shown in FIG. 18, in response to the voltages to the input terminals I1, I2 and the terminal Ci the time t1 and the time t2, the voltages at the terminal (I1⊕I2)B, OB and CoB are the supply voltage VSS, the supply voltage VSS and the supply voltage VDD minus the threshold voltage Vth (VDD−Vth) respectively.

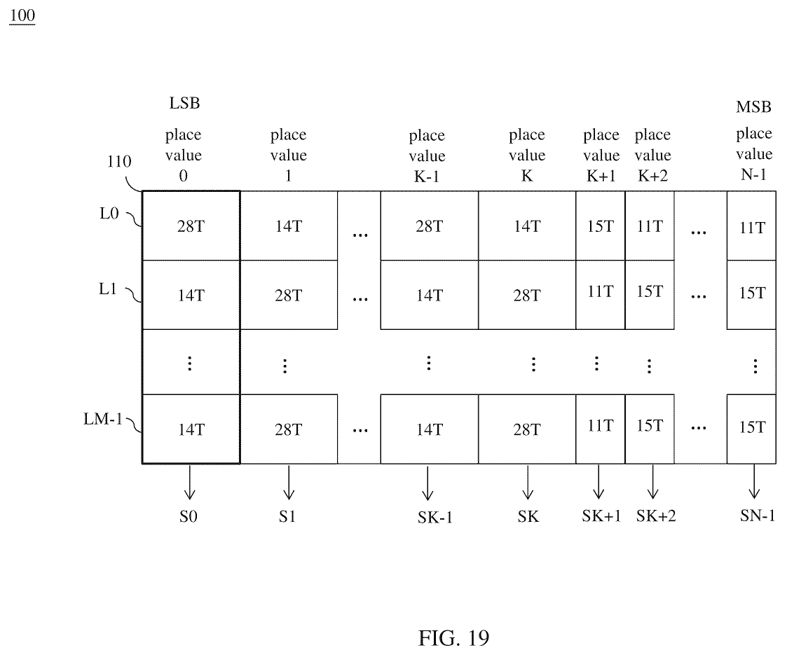

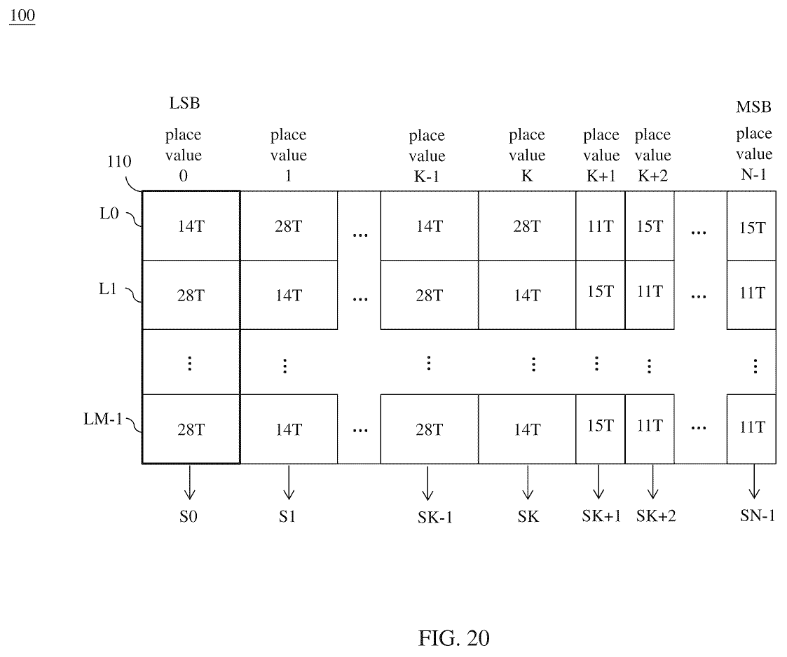

Reference is now made to FIGS. 19-20. FIGS. 19-20 are schematic diagrams showing examples of the adder tree 100 in FIGS. 1-4, in accordance with various embodiments of the present disclosure.

In FIG. 19, each column corresponds to the structure 110 and each row corresponds to a layer of the structures 110. The layers L0-LM−1 are M layers of the structure 110, in which M is an integer.

In some embodiments, the structures 110 corresponding to the lower bits (place value 0 to place value K−1) include full swing adders (e.g., 14T and 28T adders) and the structures 110 corresponding to the upper bits (place value K to place value N−1) include non full swing adders (e.g., 11T and 15T adders).

According to some embodiments, the upper bits of the number inputted to the adder tree 100 have higher probability of being “0” due to some operations in the computing circuit 30 (e.g., mantissa alignment). Therefore, the structures 110 corresponding to the upper bits are configured with non full swing adders that provide full swing outputs when inputs are bits “0” to save energy and area.

In some embodiments, the structures 110 corresponding to the lower bits (place value 0 to place value K−1) include includes the 28T adders 111 as shown in FIG. 5 and the 14T adders as shown in FIG. 6 that are arranged alternately. For example, in the structure 110 of the place value 0, the adders 111 in the layer L0 are the 28T adders as shown in FIG. 5, and the adders 111 in the layer L1 are the 14T adders as shown in FIG. 5.

In some embodiments, the structures 110 corresponding to the upper bits (place value K to place value N−1) includes the 15T adder 111 as shown in FIG. 11 and the 11T adder as shown in FIG. 17 that are arranged alternately. For example, in the structure 110 of the place value K+1, the adders 111 in the layer L0 are the 15T adders as shown in FIG. 11, and the adders 111 in the layer L1 are the 11T adders as shown in FIG. 17. In such embodiments, the critical patterns to the input terminals I1, I2 and the terminal Ci of the adders 111 are “000” and “010”.

The configurations of FIG. 19 are given for illustrative purposes. Various implements are within the contemplated scope of the present disclosure. The order of the 28T and 14T adders can be changed. The order of the 15T and 11T adders can be changed. For example, as shown in FIG. 20, the adder 111 in the layer L0 in the structure 110 of the place value 0 is the 14T adder and the adder 111 in the layer L0 in the structure 110 of the place value K+1 is the 11T adder.

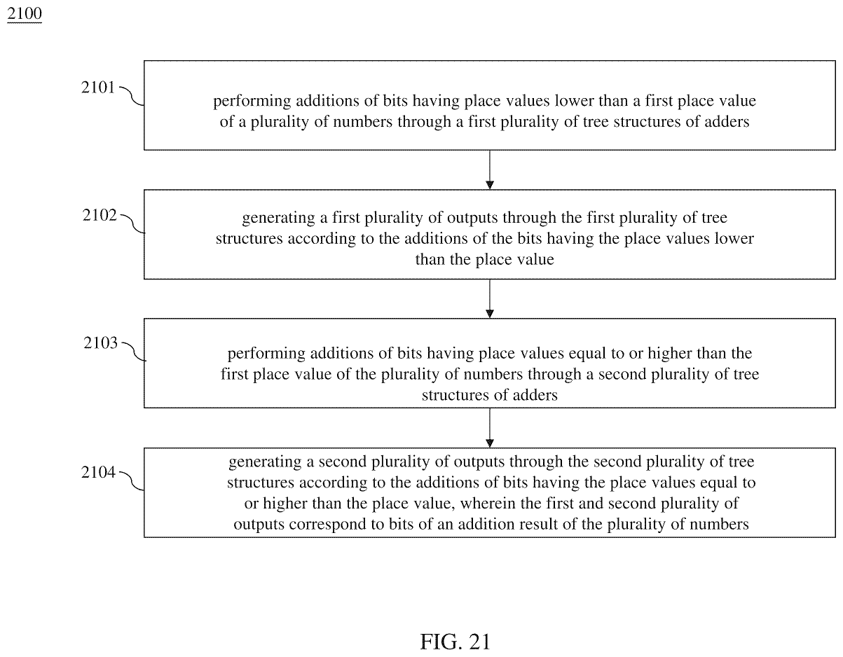

Reference is now made to FIG. 21. FIG. 21 is a flowchart diagram of a method 2100 for operating the AI accelerator 10, the adder tree 100, and the adder 111 as shown in FIGS. 1-7, 8A-8C, 9A-9C, 10A-10C, 11-13, 14A-14C, 15A-15C, 16A-16C, 17-20 in accordance with some embodiments of the present disclosure. It is understood that additional operations can be provided before, during, and after the operations shown by FIG. 21, and some of the operations described below can be replaced or eliminated, for additional embodiments of the method. The order of the operations may be interchangeable. The method 2100 includes operations 2101-2104 that are described below with reference to the AI accelerator 10, the adder tree 100, and the adder 111 as shown in FIGS. 1-7, 8A-8C, 9A-9C, 10A-10C, 11-13, 14A-14C, 15A-15C, 16A-16C, 17-20.

In operation 2101, the structures 110 corresponding to the place value 0 to place value K as shown in FIG. 19 perform additions of bits having place values lower than the place value K+1 of multiple N-bit numbers inputted to the adder tree 100.

In operation 2102, the structures 110 corresponding to the place value 0 to place value K generate the output bits S0-SK according to the additions of bits having place values lower than the place value K+1.

In operation 2103, the structures 110 corresponding to the place value K+1 to place value N−1 as shown in FIG. 19 perform additions of bits having place values equal to or higher than the place value K+1 of the N-bit numbers.

In operation 2104, the structures 110 corresponding to the place value K+1 to place value N−1 generate the output bits SK+1-SN−1 according to the additions of bits having place values equal to or higher than the place value K+1. The bits S0-SN−1 correspond to N bits of an addition result of the N-bit numbers. In some embodiments, the bits SK+1 to SN−1 are non full swing outputs according to the inputted bits. For example, the bits SK+1 is non full swing when the input bits to the adder 111 in the layer LM−1 do not match the critical patterns as described above.

In some embodiments, the adders 111 of the structure 110 corresponding to the place value K generate carry bits to the corresponding adders 111 of the structure 110 corresponding to the place value K+1. The adders 111 of the structure 110 corresponding to the place value K+1 perform additions between the carry bits and bits corresponding to the place value K+1 in the N-bit numbers to generate the bit SK+1.

As described above, circuit and operating method of adder tree are provided. The adder tree are design to provide full swing outputs for critical patterns while having fewer transistors to reduce the consumption of energy and area. For the case that the inputs do not match the critical patterns and non full swing outputs are generated, ULVT MOSs are used to reduce the impact of the threshold drop.

In some embodiments, a circuit is provided. The circuit comprises first and second plurality of tree structures of adders. The first plurality of tree structures are configured to perform additions of bits lower than a place value of a plurality of numbers. The adders in the first plurality of tree structures are configured to generate full swing outputs. The second plurality of tree structures of adders are coupled to the first plurality of tree structures of adders. The second plurality of tree structures are configured to perform additions of bits equal to or higher than the place value of the plurality of numbers. The second plurality of tree structures include transistors fewer than transistors of the first plurality of tree structures. One of the adders in the second plurality of tree structures is configured to generate a non full swing output in response to bits inputted to the adder in the second plurality of tree structures matching a pattern.

In some embodiments, a circuit is provided. The circuit, comprises a plurality tree structures of adders. Each of the tree structure comprises first layers of first adders and second layers of second adders that are arranged alternately. One of the first adders includes an n type transistor or a p type transistor that are coupled between a first supply voltage and a second supply voltage lower than the first supply voltage. The n type transistor transmits the first supply voltage in response to bits inputted to the first adder matching a pattern, and the p type transistor transmits the second supply voltage in response to the bits inputted to the first adder matching the pattern An amount of transistors of each of the first adders is smaller than an amount of transistors of each of the second adders.

In some embodiments, a method is provided. The method comprises: performing additions of bits having place values lower than a first place value of a plurality of numbers through a first plurality of tree structures of adders; generating a first plurality of outputs through the first plurality of tree structures according to the additions of the bits having the place values lower than the place value; performing additions of bits having place values equal to or higher than the place value of the plurality of numbers through a second plurality of tree structures of adders; and generating a second plurality of outputs through the second plurality of tree structures according to the additions of bits having the place values equal to or higher than the place value. The first and second plurality of outputs correspond to bits of an addition result of the plurality of numbers. The second plurality of outputs are non full swing outputs according to the bits having place values equal to or higher than the place value of the plurality of numbers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a first plurality of tree structures of adders, wherein the first plurality of tree structures are configured to perform additions of bits of a plurality of numbers having place values lower than a predetermined place value;
wherein the adders in the first plurality of tree structures are configured to generate full swing outputs; and
a second plurality of tree structures of adders coupled to the first plurality of tree structures of adders, wherein the second plurality of tree structures are configured to perform additions of bits of the plurality of numbers having place values equal to or higher than the predetermined place value,
wherein the second plurality of tree structures include transistors fewer than transistors of the first plurality of tree structures,
wherein one of the adders in the second plurality of tree structures is configured to generate a non full swing output in response to bits inputted to the adder in the second plurality of tree structures matching a pattern.

2. The circuit of claim 1, wherein each of the adders of a first tree structure corresponding to a lower place value in the first and second plurality of tree structures is configured to generate carry bits to a corresponding one of the adders of a second tree structure corresponding to a higher place value in the first and second plurality of tree structures.

3. The circuit of claim 1, wherein each tree structure in the first plurality of tree structures includes a first layer of first adders and a second layer of second adders receiving outputs of the first layer of the first adders,
wherein an amount of transistors of one of the first adders is greater than an amount of transistors of one of the second adders.

4. The circuit of claim 2, wherein each of the second adders comprises an inverter configured to transfer a supply voltage to an output terminal of the second adder.

5. The circuit of claim 1, wherein the second plurality of tree structures include a plurality of first adders and a plurality of second adders, wherein a first amount of transistors in each of the first adders is smaller than a second amount of transistors in each of the second adders.

6. The circuit of claim 5, wherein one of the first adders comprises:
a first XOR gate coupled to first and second input terminals of the first adder;
a second XOR gate coupled between the first XOR gate and an output terminal of the first adder; and
a multiplexer configured to select among a voltage of the second input terminal and a voltage of an input carry bit to generate a voltage of an output carry bit according to a first output voltage of the first XOR gate.

7. The circuit of claim 6, wherein the first XOR gate comprises:
a first transistor coupled between the second input terminal and the first output voltage;
a second transistor coupled between the first output voltage and a voltage inverted to a voltage at second input terminal; and
a third transistor coupled between the first input terminal and the second input terminal.

8. The circuit of claim 7, wherein the second XOR gate comprises:
a fourth transistor coupled between the first output voltage and the output terminal;
a fifth transistor coupled between the output terminal and a voltage inverted to the first output voltage; and
a sixth transistor coupled between the output terminal and the voltage of the input carry bit.

9. The circuit of claim 6, wherein the multiplexer comprises:
a first transistor coupled between the second input terminal and the voltage of the output carry bit;
a second transistor coupled between the voltage of the input carry bit and the voltage of the output carry bit, wherein gate terminals of the first and second transistor are coupled together; and
a third transistor coupled between the voltage of the input carry bit and the voltage of the output carry bit, wherein a gate terminal of the third transistor is coupled to the first output voltage.

10. The circuit of claim 5, wherein each of the second adders comprises:
a first XNOR gate coupled to a first input terminal of the first adder and a voltage of an input carry bit;
a first inverter coupled to an output terminal of the first adder;
a second XNOR gate coupled between the first XNOR gate and the first inverter; and
a multiplexer configured to select among a voltage of the first input terminal and a voltage of a second input terminal of the first adder for generating a voltage of an output carry bit according to a first output voltage of the first XNOR gate.

11. The circuit of claim 10, wherein the first XNOR gate comprises:
a first transistor coupled between the first output voltage and a voltage inverted to the voltage of the first input terminal;
a second transistor coupled between the first output voltage and the voltage of the first input terminal; and
a third transistor coupled between the first output voltage the voltage of the input carry bit.

12. The circuit of claim 11, wherein the second XNOR gate comprises:
a fourth transistor coupled between the first inverter and a voltage inverted to the voltage of the second input terminal;
a fifth transistor coupled between the first inverter and the voltage of the second input terminal; and
a sixth transistor coupled between the first inverter and a voltage inverted to the first output voltage.

13. The circuit of claim 10, wherein the multiplexer comprises:
a first transistor coupled to the voltage inverted to the voltage of the second input terminal;
a second transistor coupled to a voltage inverted to the voltage of the first input terminal, wherein gate terminals of the first and second transistor are coupled together to the voltage inverted to the first output voltage; and
a third transistor coupled between the voltage inverted to the voltage of the first input terminal and a gate terminal of the third transistor is coupled to the first output voltage.

14. A circuit, comprising:
a plurality tree structures of adders, wherein one of the tree structure comprises:
first layers of first adders and second layers of second adders that are arranged alternately,
wherein one of the first adders comprises an n type transistor or a p type transistor that are coupled between a first supply voltage and a second supply voltage lower than the first supply voltage,
wherein the n type transistor is configured to transmit the first supply voltage in response to bits inputted to the first adder matching a pattern, and the p type transistor is configured to transmit the second supply voltage in response to the bits inputted to the first adder matching the pattern,
wherein an amount of transistors of each of the first adders is smaller than an amount of transistors of each of the second adders.

15. The circuit of claim 14, wherein one of the first adders comprises:
a first inverter;
a first XOR gate coupled between the first inverter and first and second input terminals of the first adder;
a second XOR gate coupled between the first inverter and an output terminal of the first adder; and
a MUX configured to select from a voltage of the second input terminal and a voltage of an input carry bit to generate a voltage of an output carry bit.

16. The circuit of claim 15, wherein the first inverter comprises:
a first transistor coupled between the first supply voltage and the second XOR gate; and
a second transistor coupled between the second supply voltage and the second XOR gate.

17. The circuit of claim 14, wherein each of the second adders comprises:
a first XNOR gate coupled to a first input terminal of the first adder and a voltage of an input carry bit;
a first inverter coupled to the first XNOR gate;
a second inverter coupled to an output terminal of the first adder;
a second XNOR gate coupled between the first inverter and the second inverter; and
a multiplexer configured to select among a voltage of the first input terminal and a voltage of a second input terminal of the first adder for generating a voltage of an output carry bit according to a first output voltage of the first XNOR gate.

18. The circuit of claim 17, wherein the first inverter comprises:
a first transistor coupled between the first supply voltage and the second XNOR gate; and
a second transistor coupled between the second supply voltage and the second XNOR gate.

19. A method, comprising:
performing additions of bits having place values lower than a first place value of a plurality of numbers through a first plurality of tree structures of adders;
generating a first plurality of outputs through the first plurality of tree structures according to the additions of the bits having the place values lower than the place value;
performing additions of bits having place values equal to or higher than the place value of the plurality of numbers through a second plurality of tree structures of adders; and
generating a second plurality of outputs through the second plurality of tree structures according to the additions of bits having the place values equal to or higher than the place value,
wherein the first and second plurality of outputs correspond to bits of an addition result of the plurality of numbers,
wherein the second plurality of outputs are non full swing outputs according to the bits having place values equal to or higher than the place value of the plurality of numbers.

20. The method of claim 19, comprising:
generating carry bits through the adders of a first tree structure corresponding to a highest place value in the first plurality of tree structures;
receiving the carry bits through the adders of a second tree structure corresponding to a lowest place value in the second plurality of tree structure; and
performing additions between the carry bits and bits corresponding to the lowest place value in the plurality of numbers through the adders of the second tree structure.
